(19) United States
(12) Patent Application Publication
(10) Pub. No.: US 2025/0357288 A1
(43) Pub. Date: Nov. 20, 2025

(54) PACKAGE COMPRISING A SUBSTRATE, AN INTEGRATED DEVICE AND AN INTERCONNECT OVER THE INTEGRATED DEVICE

(71) Applicant: QUALCOMM Incorporated, San Diego, CA (US)

(72) Inventors: Aniket PATIL, San Diego, CA (US); Yujen CHEN, Taichung (TW); Yangyang SUN, San Diego, CA (US)

(21) Appl. No.: 18/664,060

(22) Filed: May 14, 2024

(51) Int. Cl. H01L 23/498; H01L 23/00; H01L 23/29; H01L 23/31; H01L 25/065

(52) U.S. Cl. CPC H01L 23/49816; H01L 23/291; H01L 23/295; H01L 23/3135; H01L 23/49838; H01L 23/49866; H01L 24/13; H01L 24/16; H01L 24/29; H01L 24/32; H01L 24/73; H01L 25/0655; H01L 2224/1357; H01L 2224/16227; H01L 2224/2919; H01L 2224/32225; H01L 2224/73204; H01L 2924/37001

(57) ABSTRACT

A package comprising a substrate; a first integrated device coupled to the substrate through at least a first plurality of solder interconnects; an underfill located between the first integrated device and the substrate; and a back side interconnect located over the underfill and a back side of the first integrated device.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a substrate; a first integrated device coupled to the substrate through at least a first plurality of solder interconnects; an underfill located between the first integrated device and the substrate; and a back side interconnect located over the underfill and a back side of the first integrated device.

Another example provides a method for fabricating a package. The method provides a substrate. The method couples a first integrated device to the substrate through at least a first plurality of solder interconnects. The method forms an underfill between the first integrated device and the substrate. The method forms a back side interconnect located over the underfill and a back side of the first integrated device.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a substrate, an integrated device and a back side interconnect.

FIG. 2 illustrates an exemplary cross sectional profile view of a package that includes a substrate, an integrated device and a back side interconnect.

FIG. 3 illustrates an exemplary electrical path for a package that includes a substrate, an integrated device and a back side interconnect.

FIG. 4 illustrates an exemplary plan view of a package that includes a substrate, an integrated device and a back side interconnect.

FIG. 5 illustrates an exemplary cross sectional profile view of a package that includes a substrate, an integrated device and a back side interconnect.

FIG. 6 illustrates an exemplary cross sectional profile view of a package that includes a substrate, an integrated device and a back side interconnect.

FIG. 7 illustrates an exemplary electrical path for a package that includes a substrate, an integrated device and a back side interconnect.

FIG. 8 illustrates an exemplary plan view of a package that includes a substrate, an integrated device and a back side interconnect.

FIGS. 9A-9C illustrate an exemplary sequence for fabricating a package that includes a substrate, an integrated device and a back side interconnect.

FIG. 10 illustrates an exemplary flow chart of a method for fabricating a package that includes a substrate, an integrated device and a back side interconnect.

FIGS. 11A-11B illustrate an exemplary sequence for fabricating a substrate.

FIG. 12 illustrates an exemplary flow chart of a method for fabricating a substrate.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure a package comprising a substrate; a first integrated device coupled to the substrate through at least a first plurality of solder interconnects; an underfill located between the first integrated device and the substrate; and a back side interconnect located over the underfill and a back side of the first integrated device. The use of the back side interconnect helps provide additional electrical paths without adding metal layers in the substrate.

### Exemplary Package Comprising a Back Side Interconnect Over an Integrated Device and an Underfill

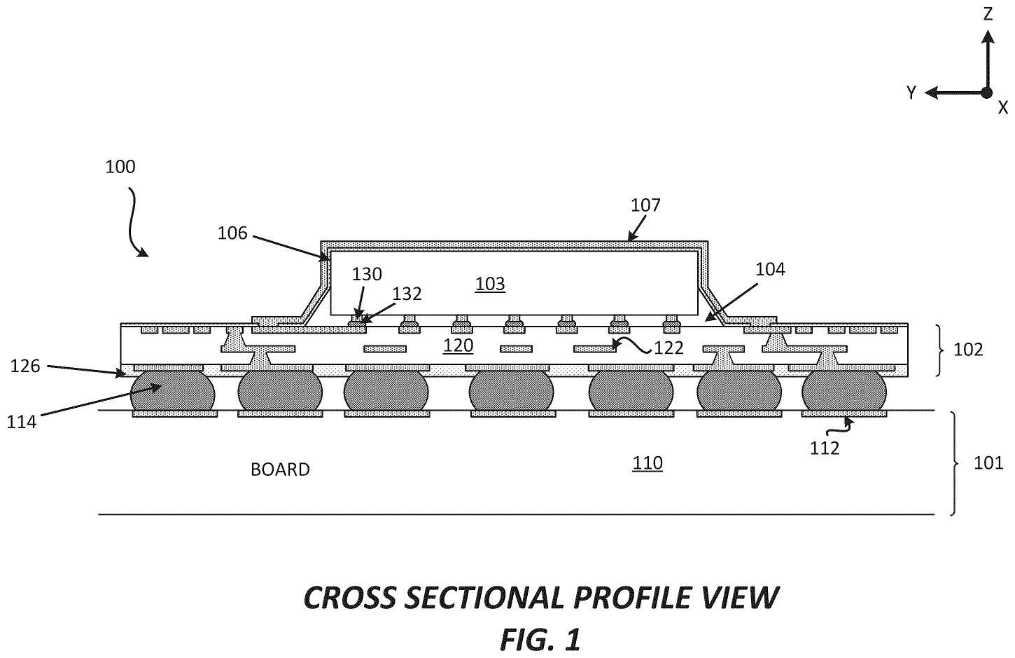

FIG. 1 illustrates a cross sectional profile view of a package 100 that includes back side interconnects. The package 100 may be implemented as part of a package on package (PoP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102, an integrated device 103, an underfill 104, a back side dielectric layer 106 and a plurality of back side interconnects 107. The substrate 102 includes a dielectric layer 120, a plurality of interconnects 122 and a solder resist layer 126. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The substrate 102 is coupled to the board 101 through the plurality of solder interconnects 114.

The underfill 104 is located between the integrated device 103 and the substrate 102. The underfill 104 may at least laterally surround the plurality of pillar interconnects 130 and/or the plurality of solder interconnects 132. The underfill 104 may be coupled to and touch a side wall of the integrated device 103. In some implementations, the underfill 104 may include a composite material comprising an epoxy polymer with filler. In some implementations, an encapsulation layer (not shown) may be formed and coupled to the substrate 102. The encapsulation layer may be formed over the substrate 102, the integrated device 103, the back side dielectric layer 106 and/or the plurality of back side interconnects 107. The encapsulation layer may at least partially encapsulate the integrated device 103, the back side dielectric layer 106 and/or the plurality of back side interconnects 107. The encapsulation layer may include a mold, a resin and/or an epoxy. The encapsulation layer may be a means for encapsulation. The encapsulation layer may be provided by using a compression and transfer molding process, a sheet molding process, or a liquid molding process. The encapsulation layer may be different from the underfill 104. For example, the encapsulation layer may include a different material and/or a different composition of material from the underfill 104.

The back side dielectric layer 106 may be located over one or more surfaces of the underfill 104 and/or one or more surfaces of the integrated device 103. The back side dielectric layer 106 may be coupled to and touch the substrate 102. The back side dielectric layer 106 may be coupled to and touch a surface of the underfill 104. The back side dielectric layer 106 may be coupled to and touch a side surface of the integrated device 103. The back side dielectric layer 106 may be coupled to and touch a back side surface of the integrated device 103. The back side surface of the integrated device 103 may include a surface of a back side of the integrated device 103. The back side of the integrated device 103 may include a die substrate (e.g., silicon substrate). The back side dielectric layer 106 may include silicon oxide (e.g., silicon dioxide). The back side dielectric layer 106 may include a different material from the at least one dielectric layer 120 of the substrate 102. A vapor deposition process (e.g., micro vapor deposition process) may be used to form the back side dielectric layer 106. Different implementations may use different materials for the dielectric layer 106, such as prepreg and/or polyimide.

The plurality of back side interconnects 107 may be located over the underfill 104 and/or the integrated device 103. The plurality of back side interconnects 107 may be located over a back side of the integrated device 103. The plurality of back side interconnects 107 may be coupled to and touch the back side dielectric layer 106. The plurality of back side interconnects 107 may be coupled to the plurality of interconnects 122 of the substrate 102. The back side dielectric layer 106 may be located between the plurality of back side interconnects 107 and the underfill 104. The back side dielectric layer 106 may be located between the plurality of back side interconnects 107 and the integrated device 103. The back side dielectric layer 106 may be located between the plurality of back side interconnects 107 and at least one side surface of the integrated device 103. The back side dielectric layer 106 may be located between the plurality of back side interconnects 107 and a back side surface of the integrated device 103. The plurality of back side interconnects 107 may include copper (Cu) or silver (Ag). The plurality of back side interconnects 107 may include inkjet printed interconnects.

The use of the plurality of back side interconnects 107 helps optimize and increase the number of interconnects and/or electrical paths in an package without having the increase the size and/or thickness of a substrate. By utilizing a space and/or a region that was previously unused in a package, improved routing of electrical signals can be achieved, such as routing of signals that minimally interfere with each other. Routing of signals can be done from one side of the integrated device to another side of the substrate, where there might be more space for routing of interconnects.

In some implementations, the use of the back side dielectric layer 106 may be optional, or the back side dielectric layer 106 may cover only some components. In one example, the back side dielectric layer 106 may be coupled to the side surface and/or the back side surface of the integrated device 103. Thus, for example, the back side dielectric layer 106 may be coupled to and touch the die substrate (e.g., silicon substrate) of the integrated device 103.

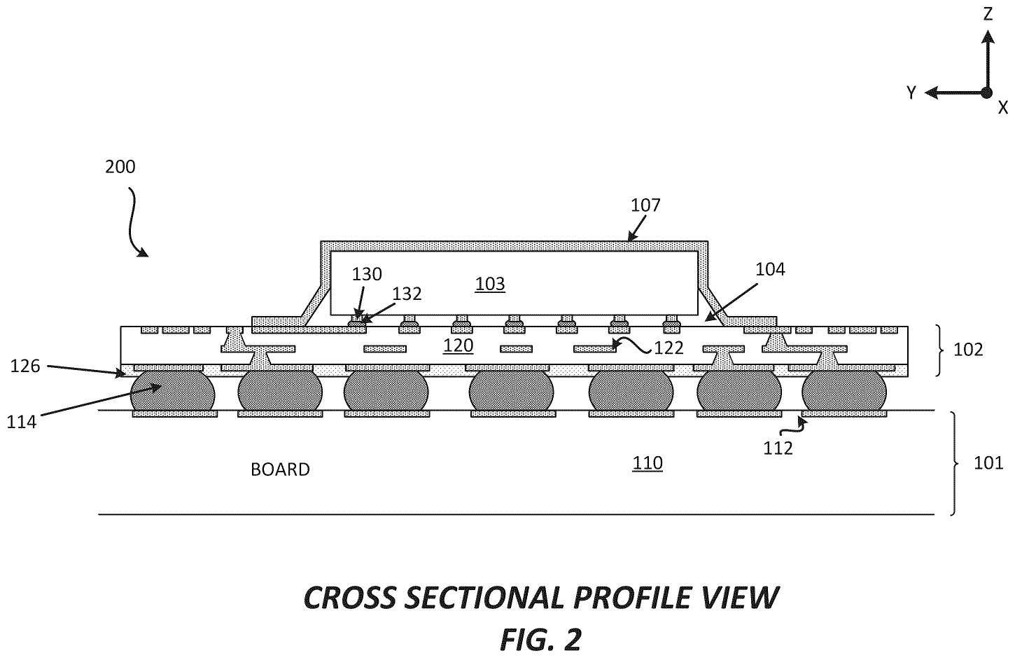

FIG. 2 illustrates a package 200. The package 200 is similar to the package 100, and may include similar components that are arranged in a similar manner as components described for the package 100 of FIG. 1. The package 200 includes a substrate 102, an integrated device 103, an underfill 104, and a plurality of back side interconnects 107. The substrate 102 includes a dielectric layer 120, a plurality of interconnects 122 and a solder resist layer 126. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The substrate 102 is coupled to the board 101 through the plurality of solder interconnects 114.

The underfill 104 is located between the integrated device 103 and the substrate 102. The underfill 104 may at least laterally surround the plurality of pillar interconnects 130 and/or the plurality of solder interconnects 132. The underfill 104 may be coupled to and touch a side wall of the integrated device 103.

The plurality of back side interconnects 107 may be located over the underfill 104 and/or the integrated device 103. The plurality of back side interconnects 107 may be located over, coupled to and touching at least one surface of the underfill 104. The plurality of back side interconnects 107 may be located over, coupled to and touching a back side of the integrated device 103. The plurality of back side interconnects 107 may include copper (Cu) or silver (Ag). The plurality of back side interconnects 107 may include inkjet printed interconnects. Thus, in FIG. 2, there is no back side dielectric layer, similar to the back side dielectric layer 106. However, as mentioned above, there may be a back side dielectric layer that is coupled to some portion of the underfill 104 and/or some portion of the integrated device 103.

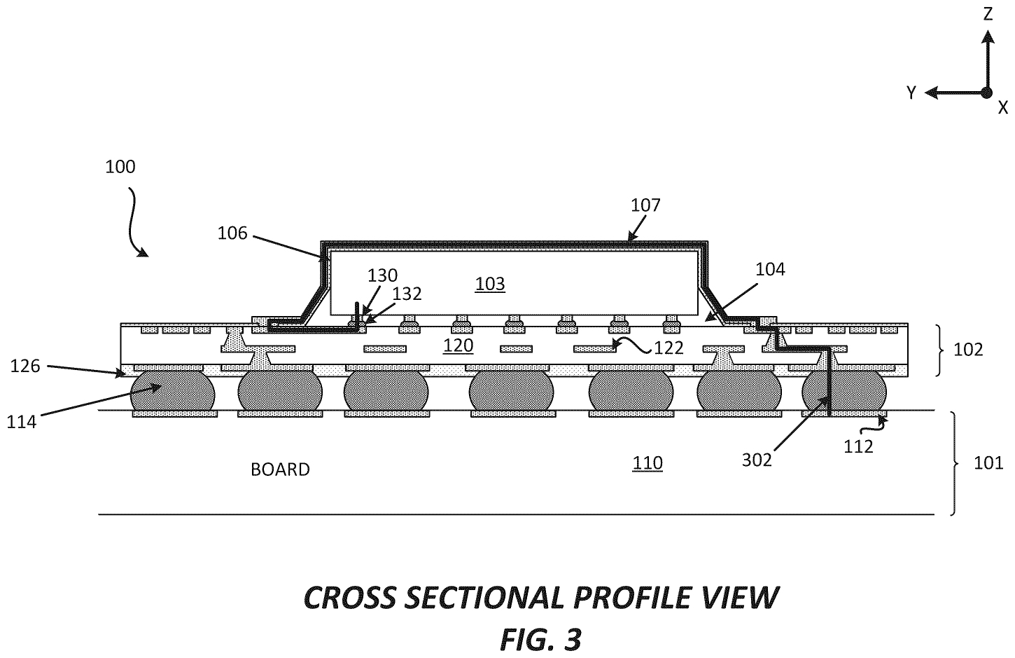

FIG. 3 illustrates an example of an electrical path for the package 100. The electrical path 302 may include a pillar interconnect from the plurality of pillar interconnects 130, a solder interconnect from the plurality of solder interconnects 132, at least one interconnect from the plurality of interconnects 122, at least one back side interconnect from the plurality of back side interconnects 107, at least one other interconnect from the plurality of interconnects 122, a solder interconnect from the plurality of solder interconnects 114 and a board interconnect from the plurality of board interconnects 112.

FIG. 3 illustrates an example of an electrical signal that may travel from the left hand side of the integrated device 103, through a left hand side of the substrate 102, over the underfill 104, over a first side surface of the integrated device 103, over a back side surface of the integrated device 103, over a second side surface of the integrated device 103, and through a right hand side of the substrate 102.

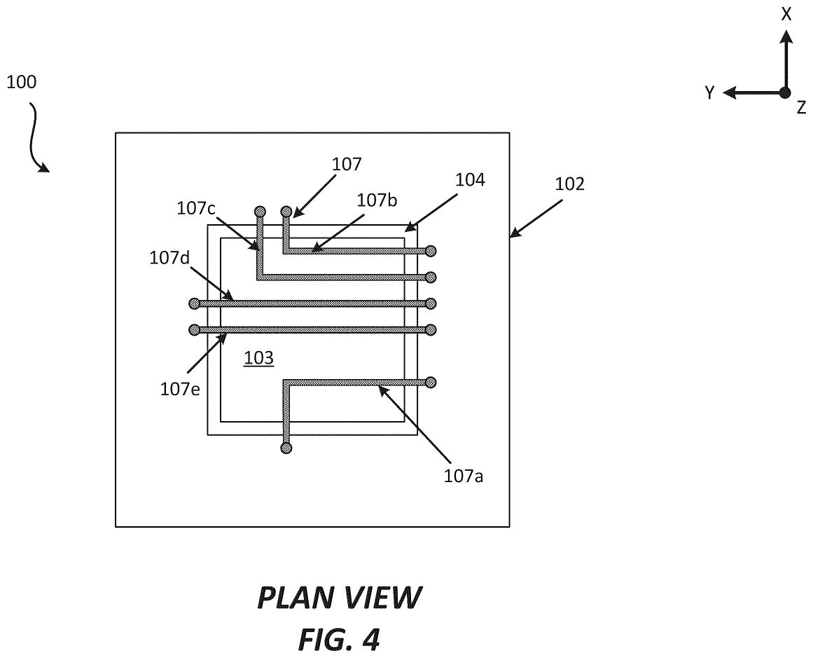

FIG. 4 illustrates a plan view of the package 100 that includes the plurality of back side interconnects 107. For purpose of clarity, the back side dielectric layer 106 is not shown. In some implementations, FIG. 4 may represent the package 200 of FIG. 2. The plurality of back side interconnects 107 may include a back side interconnect 107a, a back side interconnect 107b, a back side interconnect 107c, a back side interconnect 107d, and a back side interconnect 107e.

The back side interconnect 107a may extend over a first side of the underfill 104, a first side of the integrated device 103, the back side of the integrated device 103, a second side of the integrated device 103 and a second side of the underfill 104. The back side interconnect 107b may extend over a third side of the underfill 104, a third side of the integrated device 103, the back side of the integrated device 103, the second side of the integrated device 103 and the second side of the underfill 104. The back side interconnect 107c may extend over a third side of the underfill 104, the third side of the integrated device 103, the back side of the integrated device 103, the second side of the integrated device 103 and the second side of the underfill 104. The back side interconnect 107d may extend over a fourth side of the underfill 104, a fourth side of the integrated device 103, the back side of the integrated device 103, the second side of the integrated device 103 and the second side of the underfill 104. The back side interconnect 107e may extend over the fourth side of the underfill 104, the fourth side of the integrated device 103, the back side of the integrated device 103, the second side of the integrated device 103 and the second side of the underfill 104.

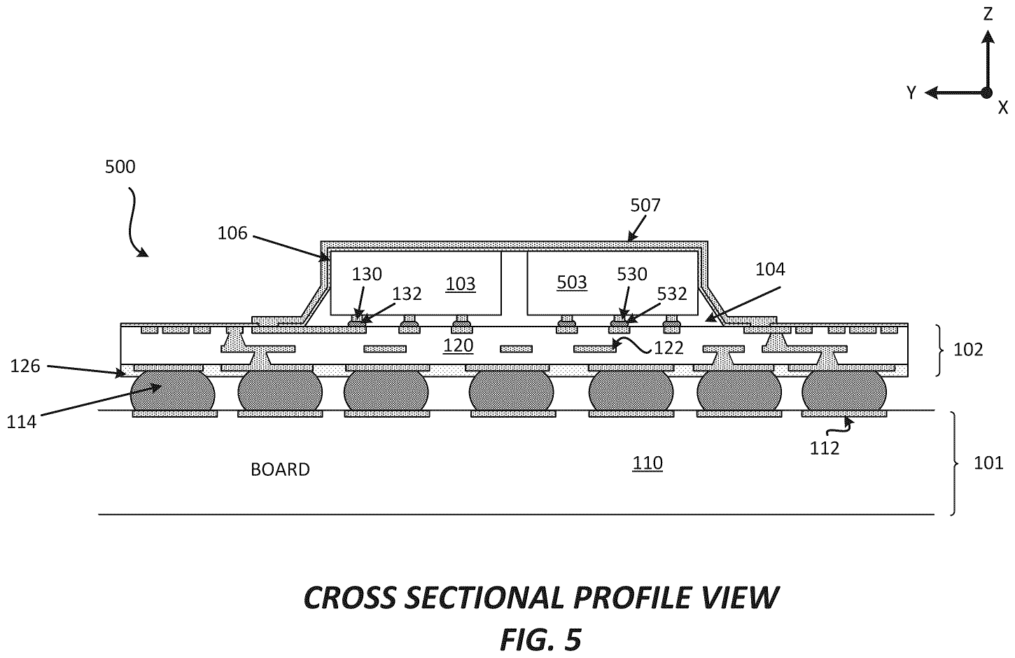

FIG. 5 illustrates a cross sectional profile view of a package 500 that includes back side interconnects. The package 500 may be implemented as part of a package on package (PoP). The package 500 is coupled to a board 101 through a plurality of solder interconnects 114. The board 101 includes at least one board dielectric layer 110 and a plurality of board interconnects 112. The board 101 may include a printed circuit board (PCB).

The package 500 includes a substrate 102, an integrated device 103, an integrated device 503, an underfill 104, a back side dielectric layer 106 and a plurality of back side interconnects 507. The substrate 102 includes a dielectric layer 120, a plurality of interconnects 122 and a solder resist layer 126. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 503 is coupled to the substrate 102 through at least a plurality of solder interconnects 532. For example, the integrated device 503 is coupled to a plurality of interconnects 122 of the substrate 102 through a plurality of pillar interconnects 530 and/or a plurality of solder interconnects 532. The substrate 102 is coupled to the board 101 through the plurality of solder interconnects 114.

The underfill 104 is located between the integrated device 103 and the substrate 102. The underfill 104 may at least laterally surround the plurality of pillar interconnects 130 and/or the plurality of solder interconnects 132. The underfill 104 may be coupled to and touch a side wall of the integrated device 103. The underfill 104 is located between the integrated device 503 and the substrate 102. The underfill 104 may at least laterally surround the plurality of pillar interconnects 530 and/or the plurality of solder interconnects 532. The underfill 104 may be coupled to and touch a side wall of the integrated device 503.

The back side dielectric layer 106 may be located over one or more surfaces of the underfill 104, one or more surfaces of the integrated device 103 and/or one or more surfaces of the integrated device 103. The back side dielectric layer 106 may be coupled to and touch the substrate 102. The back side dielectric layer 106 may be coupled to and touch a surface of the underfill 104. The back side dielectric layer 106 may be coupled to and touch a side surface of the integrated device 103. The back side dielectric layer 106 may be coupled to and touch a back side surface of the integrated device 103. The back side surface of the integrated device 103 may include a surface of a back side of the integrated device 103. The back side of the integrated device 103 may include a die substrate (e.g., silicon substrate).

The back side dielectric layer 106 may be located over one or more surfaces of the underfill 104, one or more surfaces of the integrated device 103 and/or one or more surfaces of the integrated device 503. The back side dielectric layer 106 may be coupled to and touch the substrate 102. The back side dielectric layer 106 may be coupled to and touch a surface of the underfill 104. The back side dielectric layer 106 may be coupled to and touch a side surface of the integrated device 103. The back side dielectric layer 106 may be coupled to and touch a back side surface of the integrated device 103. The back side surface of the integrated device 103 may include a surface of a back side of the integrated device 103. The back side of the integrated device 103 may include a die substrate (e.g., silicon substrate). The back side dielectric layer 106 may be coupled to and touch a side surface of the integrated device 503. The back side dielectric layer 106 may be coupled to and touch a back side surface of the integrated device 503. The back side surface of the integrated device 503 may include a surface of a back side of the integrated device 503. The back side of the integrated device 503 may include a die substrate (e.g., silicon substrate).

The back side dielectric layer 106 may include silicon oxide (e.g., silicon dioxide). The back side dielectric layer 106 may include a different material from the at least one dielectric layer 120 of the substrate 102. A vapor deposition process (e.g., micro vapor deposition process) may be used to form the back side dielectric layer 106.

The plurality of back side interconnects 107 may be located over the underfill 104, the integrated device 103 and/or the integrated device 503. The plurality of back side interconnects 107 may be located over a back side of the integrated device 103 and a back side of the integrated device 503. The plurality of back side interconnects 107 may be coupled to and touch the back side dielectric layer 106. The plurality of back side interconnects 107 may be coupled to the plurality of interconnects 122 of the substrate 102. The back side dielectric layer 106 may be located between the plurality of back side interconnects 107 and the underfill 104. The back side dielectric layer 106 may be located between the plurality of back side interconnects 107 and the integrated device 103. The back side dielectric layer 106 may be located between the plurality of back side interconnects 107 and at least one side surface of the integrated device 103. The back side dielectric layer 106 may be located between the plurality of back side interconnects 107 and a back side surface of the integrated device 103. The back side dielectric layer 106 may be located between the plurality of back side interconnects 107 and the integrated device 503. The back side dielectric layer 106 may be located between the plurality of back side interconnects 107 and at least one side surface of the integrated device 503. The back side dielectric layer 106 may be located between the plurality of back side interconnects 107 and a back side surface of the integrated device 503. The plurality of back side interconnects 107 may include copper (Cu) or silver (Ag). The plurality of back side interconnects 107 may include inkjet printed interconnects.

In some implementations, the use of the back side dielectric layer 106 may be optional, or the back side dielectric layer 106 may cover only some components. In one example, the back side dielectric layer 106 may be coupled to the side surface the back side surface of the integrated device 103 and/or the back side surface of the integrated device 503. Thus, for example, the back side dielectric layer 106 may be coupled to and touch the die substrate (e.g., silicon substrate) of the integrated device 103 and/or the die substrate (e.g., silicon substrate) of the integrated device 503.

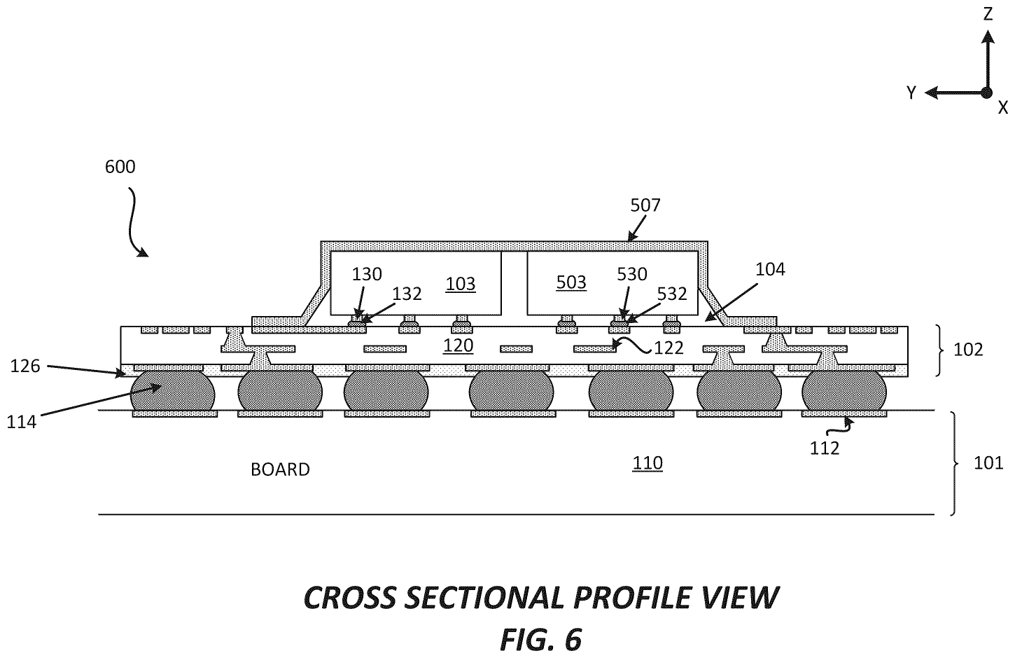

FIG. 6 illustrates a package 600. The package 600 is similar to the package 500, and may include similar components that are arranged in a similar manner as components described for the package 500 of FIG. 5. The package 600 includes a substrate 102, an integrated device 103, an integrated device 503, an underfill 104, and a plurality of back side interconnects 507. The substrate 102 includes a dielectric layer 120, a plurality of interconnects 122 and a solder resist layer 126. The integrated device 103 is coupled to the substrate 102 through at least a plurality of solder interconnects 132. For example, the integrated device 103 is coupled to a plurality of interconnects 122 of the substrate 102 through a plurality of pillar interconnects 130 and/or a plurality of solder interconnects 132. The integrated device 503 is coupled to the substrate 102 through at least a plurality of solder interconnects 532. For example, the integrated device 503 is coupled to a plurality of interconnects 122 of the substrate 102 through a plurality of pillar interconnects 530 and/or a plurality of solder interconnects 532. The substrate 102 is coupled to the board 101 through the plurality of solder interconnects 114.

The underfill 104 is located between the integrated device 103 and the substrate 102. The underfill 104 may at least laterally surround the plurality of pillar interconnects 130 and/or the plurality of solder interconnects 132. The underfill 104 may be coupled to and touch a side wall of the integrated device 103. The underfill 104 is located between the integrated device 503 and the substrate 102. The underfill 104 may at least laterally surround the plurality of pillar interconnects 530 and/or the plurality of solder interconnects 532. The underfill 104 may be coupled to and touch a side wall of the integrated device 503.

The plurality of back side interconnects 507 may be located over the underfill 104, the integrated device 103, and/or the integrated device 503. The plurality of back side interconnects 507 may be located over, coupled to and touching at least one surface of the underfill 104. The plurality of back side interconnects 507 may be located over, coupled to and touching a side surface of the integrated device 103. The plurality of back side interconnects 507 may be located over, coupled to and touching a back side of the integrated device 103. The plurality of back side interconnects 507 may be located over, coupled to and touching a back side of the integrated device 503. The plurality of back side interconnects 507 may be located over, coupled to and touching a side surface of the integrated device 503. The plurality of back side interconnects 507 may include copper (Cu) or silver (Ag). The plurality of back side interconnects 507 may include inkjet printed interconnects. Thus, in FIG. 6, there is no back side dielectric layer, similar to the back side dielectric layer 106. However, as mentioned above, there may be a back side dielectric layer that is coupled to some portion of the underfill 104 some portion of the integrated device 103 and/or some portion of the integrated device 503.

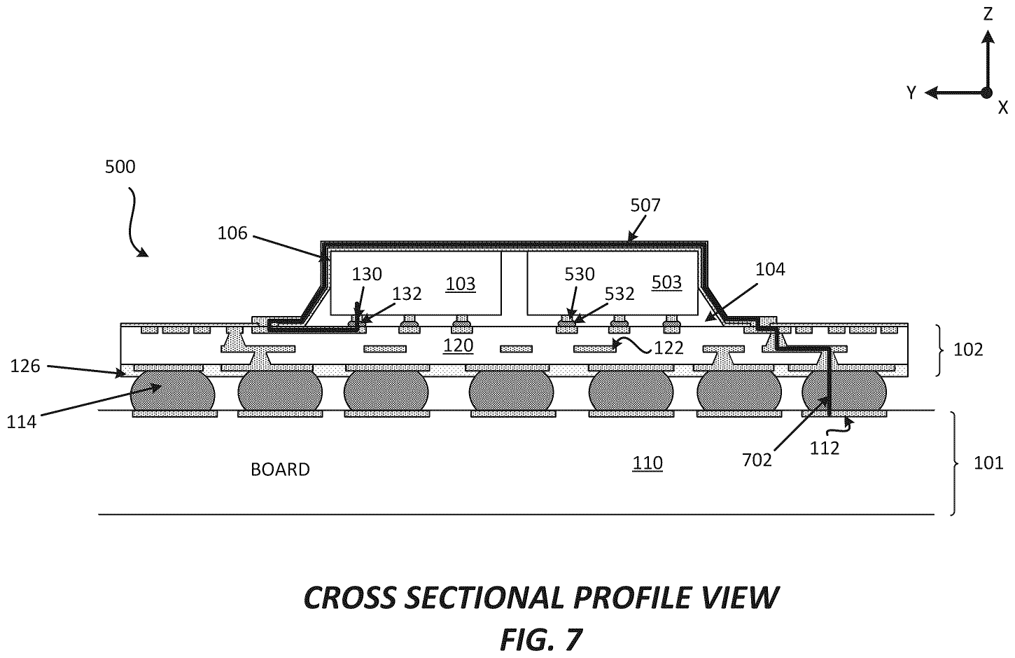

FIG. 7 illustrates an example of an electrical path for the package 500. The electrical path 702 may include a pillar interconnect from the plurality of pillar interconnects 130, a solder interconnect from the plurality of solder interconnects 132, at least one interconnect from the plurality of interconnects 122, a back side interconnect from the plurality of back side interconnects 507, at least one other interconnect from the plurality of interconnects 122, a solder interconnect from the plurality of solder interconnects 114 and a board interconnect from the plurality of board interconnects 112.

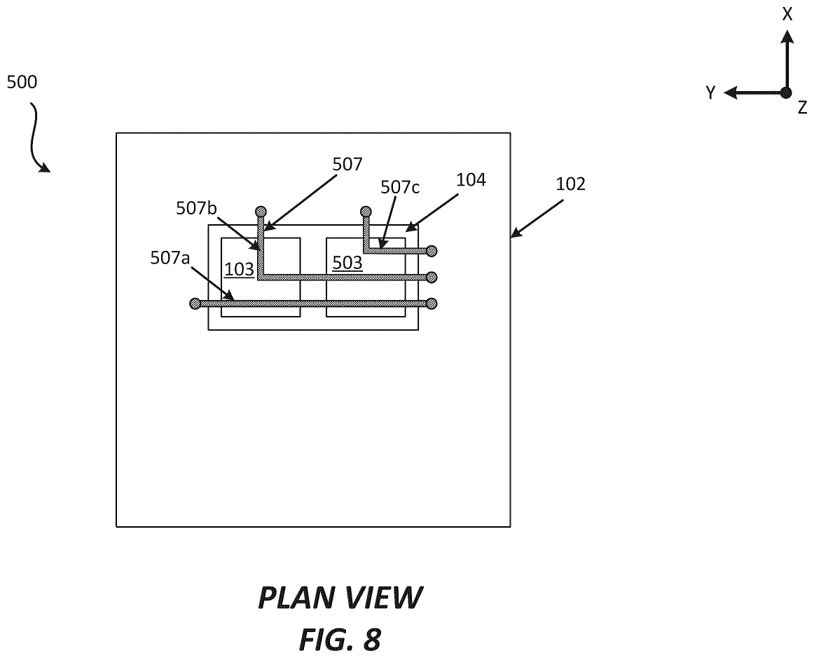

FIG. 8 illustrates an example of an electrical signal that may travel from the left hand side of the integrated device 103, through a left hand side of the substrate 102, over the underfill 104, over a first side surface of the integrated device 103, over a back side surface of the integrated device 103, over the underfill 104, over a back side surface of the integrated device 503, over a second side surface of the integrated device 503, and through a right hand side of the substrate 102.

FIG. 8 illustrates a plan view of the package 500 that includes the plurality of back side interconnects 507. For purpose of clarity, the back side dielectric layer 106 is not shown. In some implementations, FIG. 8 may represent the package 600 of FIG. 6. The plurality of back side interconnects 507 may include a back side interconnect 507a, a back side interconnect 507b, and a back side interconnect 507c.

The back side interconnect 507a may extend over a first side of the underfill 104, a first side of the integrated device 103, the back side of the integrated device 103, a top surface of the underfill 104, the back side of the integrated device 503, a second side of the integrated device 503 and a second side of the underfill 104. The back side interconnect 507b may extend over a third side of the underfill 104, a third side of the integrated device 103, the back side of the integrated device 103, a top surface of the underfill 104, the back side of the integrated device 503, the second side of the integrated device 503 and the second side of the underfill 104. The back side interconnect 507c may extend over a third side of the underfill 104, a third side of the integrated device 503, the back side of the integrated device 503, a second side of the integrated device 503 and a second side of the underfill 104. In some implementations, the back side interconnect 507a is configured to be electrically coupled to the integrated device 103. In some implementations, the back side interconnect 507b is configured to be electrically coupled to the integrated device 103. In some implementations, the back side interconnect 507c is configured to be electrically coupled to the integrated device 503. In some implementations, the back side interconnect 507a is configured to be electrically coupled to the integrated device 503. In some implementations, the back side interconnect 507b is configured to be electrically coupled to the integrated device 503.

Different implementations may have different thicknesses and/or widths for back side interconnects from the plurality of back side interconnects 107 and/or the plurality of back side interconnects 507. In some implementations, when an inkjet process is used, a minimum thickness for a back side interconnect may be about 1 micrometer or greater, and a minimum width for a back side interconnect may be about 80 micrometers. In some implementations, when a lithography process and a plating process are used, a minimum thickness for a back side interconnect may be in a range of about 5-10 micrometers or greater, and a minimum width for a back side interconnect may be about 25 micrometers. In some implementations, the plurality of back side interconnects 107 and/or the plurality of back side interconnects 507 may include a seed layer.

An integrated device (e.g., 103, 503) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc., . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 500) may be implemented in a radio frequency (RF) package. The RF package may be a radio frequency front end (RFFE) package. A package (e.g., 100, 500) may be configured to provide Wireless Fidelity (WiFi) communication and/or cellular communication (e.g., 2G, 3G, 4G, 5G). The packages (e.g., 100, 600) may be configured to support Global System for Mobile (GSM) Communications, Universal Mobile Telecommunications System (UMTS), and/or Long-Term Evolution (LTE). The packages (e.g., 100, 500) may be configured to transmit and receive signals having different frequencies and/or communication protocols.

### Exemplary Sequence for Fabricating a Package Comprising a Back Side Interconnect Over an Integrated Device and an Underfill

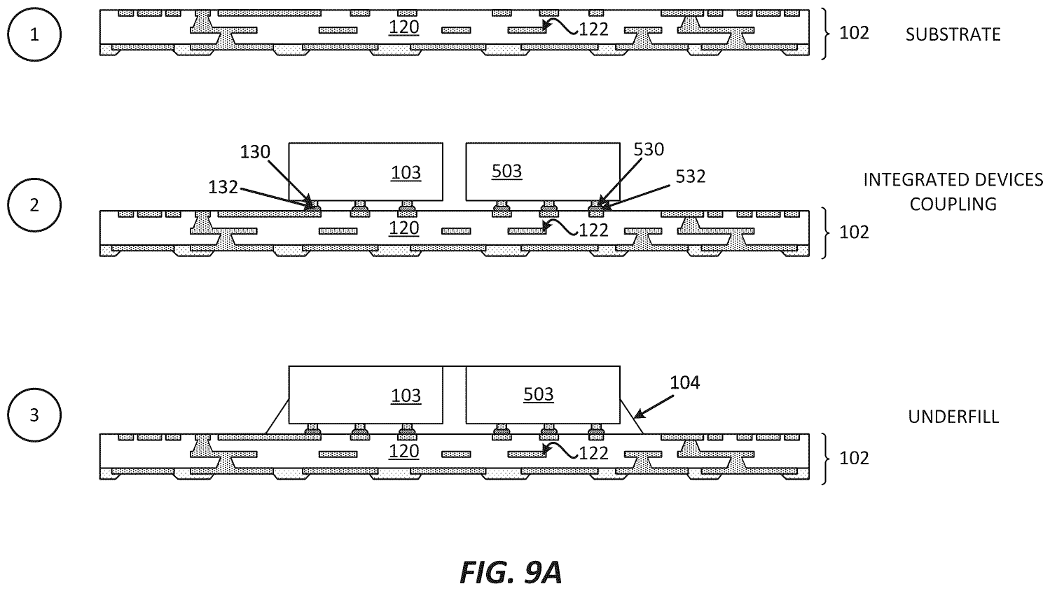

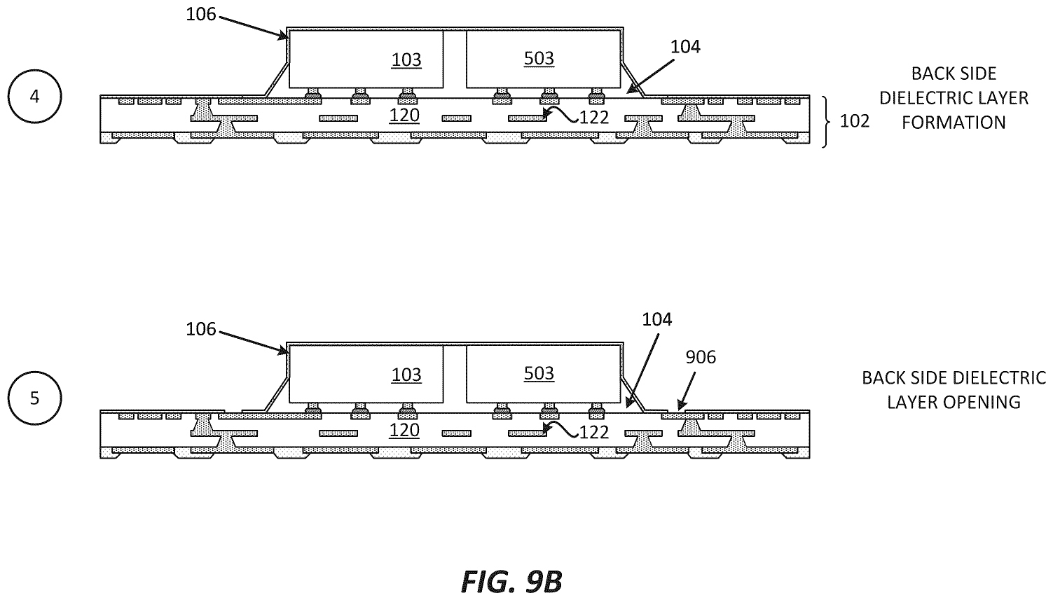

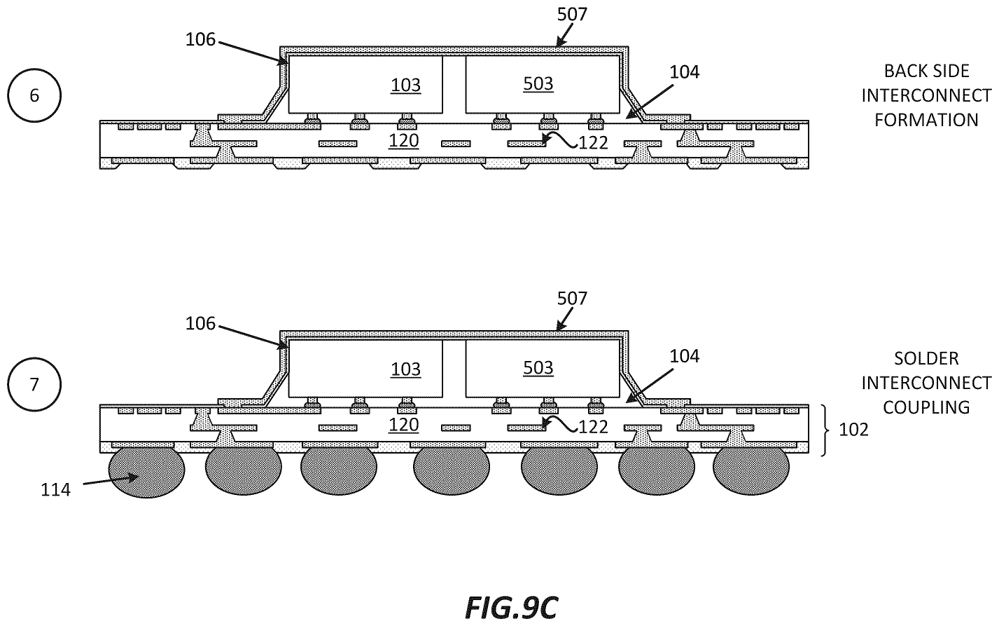

In some implementations, fabricating a package includes several processes. FIGS. 9A-9C illustrate an exemplary sequence for providing or fabricating a package. In some implementations, the sequence of FIGS. 9A-9C may be used to provide or fabricate the package 500. However, the process of FIGS. 9A-9D may be used to fabricate any of the packages (e.g., 100) described in the disclosure.

It should be noted that the sequence of FIGS. 9A-9C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

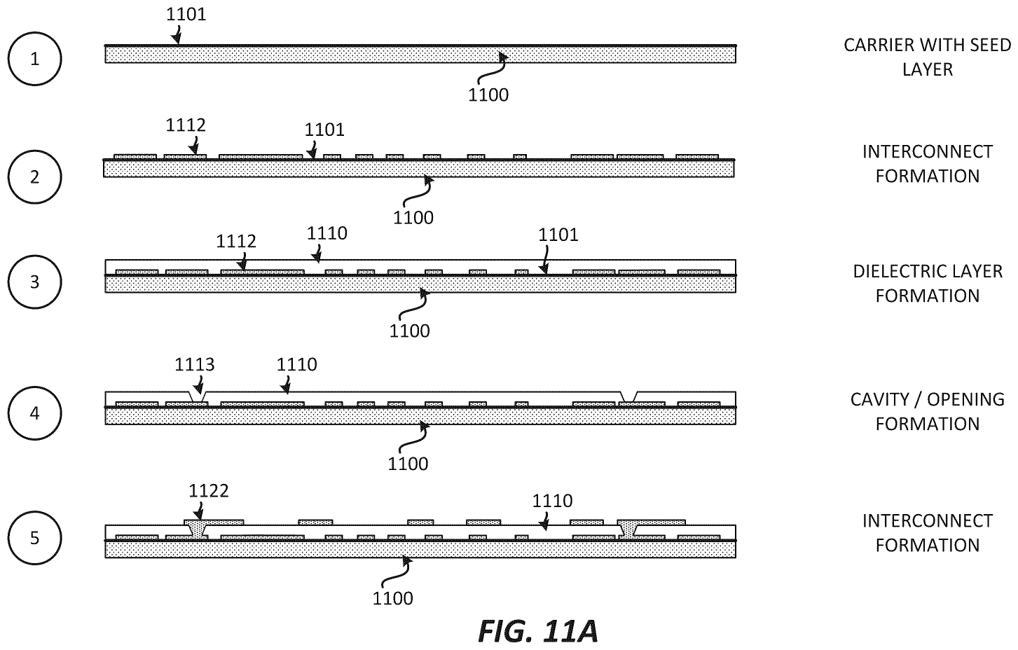

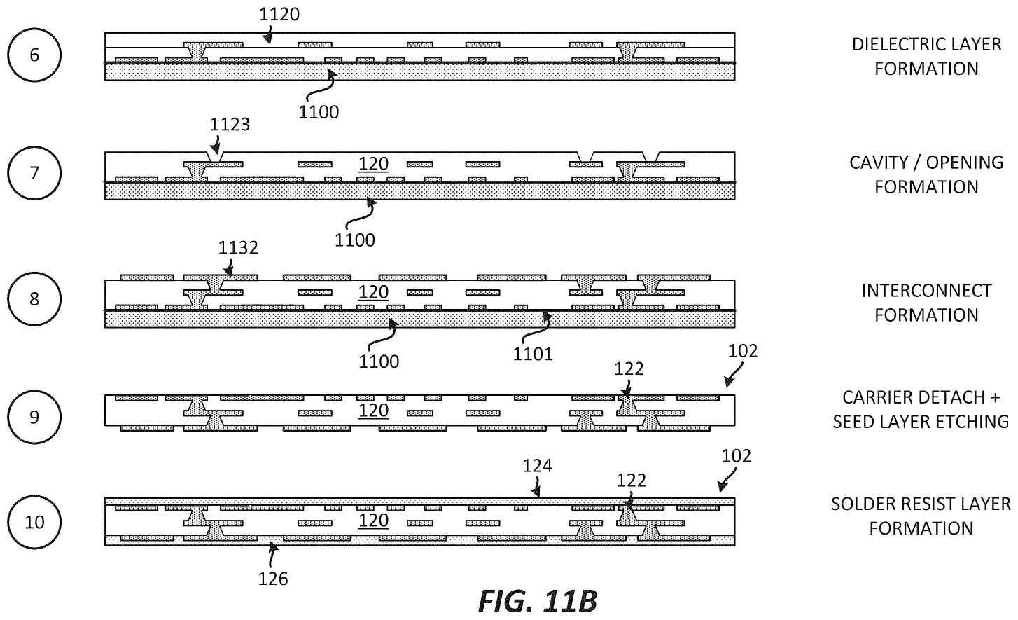

Stage 1, as shown in FIG. 9A, illustrates a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 102 may include solder resist layers. The substrate 102 may be fabricated using the method as described in FIGS. 11A-11B.

Stage 2 illustrates a state after an integrated device 103 and an integrated device 503 are coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. The integrated device 503 may be coupled to the substrate 102 through the plurality of pillar interconnects 530 and the plurality of solder interconnects 532. In some implementations, the integrated device 503 may be coupled to the substrate 102 through the plurality of solder interconnects 532. A solder reflow process may be used to couple the integrated device 103 and/or the integrated device 503 to the substrate 102.

Stage 3 illustrates a state after an underfill 104 is formed, dispensed and/or provided. The underfill 104 may be located between the integrated device 103 and the substrate 102. The underfill 104 may be located between the integrated device 503 and the substrate 102. The underfill 104 may be located between the integrated device 103 and the integrated device 503. A flow process may be used to provide the underfill 104.

Stage 4, as shown in FIG. 9B, illustrates a state after a back side dielectric layer 106 is formed and provided. The back side dielectric layer 106 may be provided over a surface of the substrate 102, a surface of the underfill 104, at least one surface of the integrated device 103 and at least one surface of the integrated device 503. A vapor deposition process (e.g., micro vapor deposition process) may be used to form the back side dielectric layer 106. The back side dielectric layer 106 may include silicon oxide (e.g., silicon dioxide). The back side dielectric layer 106 may be optional.

Stage 5 illustrates a state after a plurality of openings 906 are formed in the back side dielectric layer 106. A laser process or an etching process with a mask may be used to form the plurality of openings 906 in the back side dielectric layer 106.

Stage 6, as shown in FIG. 9C, illustrates a state after a plurality of back side interconnects 507 are formed. The plurality of back side interconnects 507 may be coupled to the plurality of interconnects 122 of the substrate 102. The plurality of back side interconnects 507 may be formed over and coupled to the back side dielectric layer 106. The plurality of back side interconnects 507 may be located over the underfill 104 and the integrated device 103 and/or the integrated device 503. When the back side dielectric layer 106 is optional, the plurality of back side interconnects 507 may be coupled to and touching a surface of the underfill 104, at least one surface of the integrated device 103 and at least one surface of the integrated device 503. An inkjet printing process may be used to form the plurality of back side interconnects 507. In some implementations, a plating process may be used to form the plurality of back side interconnects 507. The plurality of back side interconnects 507 may include silver (Ag) or copper (Cu). In some implementations, an encapsulation layer (not shown) may be formed and coupled to the substrate 102. The encapsulation layer may be formed over the substrate 102, the integrated device 103, the back side dielectric layer 106 and/or the plurality of back side interconnects 507. The encapsulation layer may at least partially encapsulate the integrated device 103, the back side dielectric layer 106 and/or the plurality of back side interconnects 507. The encapsulation layer may include a mold, a resin and/or an epoxy. The encapsulation layer may be a means for encapsulation. The encapsulation layer may be provided by using a compression and transfer molding process, a sheet molding process, or a liquid molding process. The encapsulation layer may be different from the underfill 104. For example, the encapsulation layer may include a different material and/or a different composition of material from the underfill 104.

Stage 7 illustrates a state after a plurality of solder interconnects 114 are coupled to the second surface of the substrate 102. A solder reflow process may be used to couple the plurality of solder interconnects 114 to the substrate 102. Stage 8 may illustrate the package 500.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package Comprising a Back Side Interconnect Over an Integrated Device and an Underfill

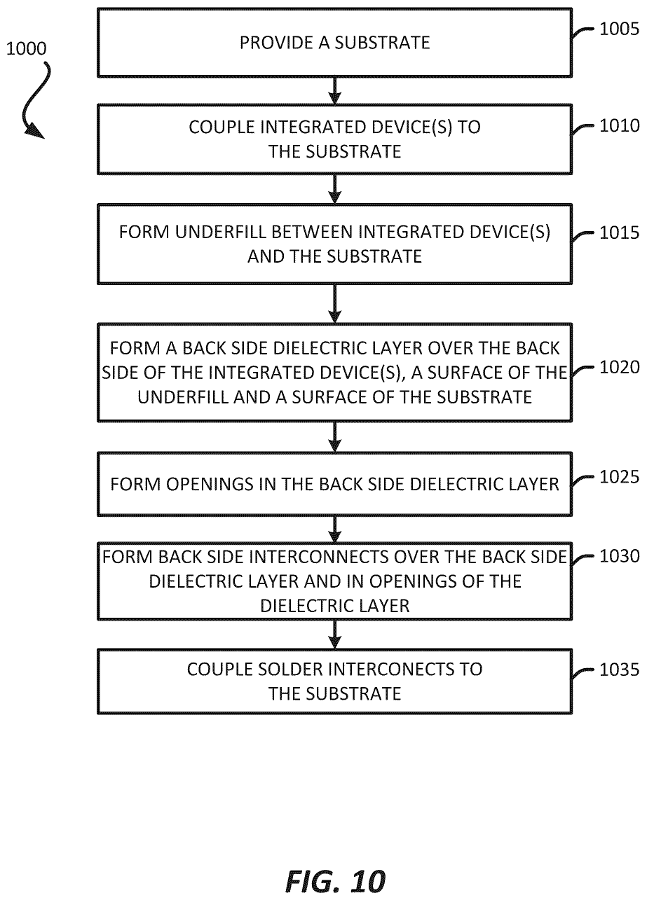

In some implementations, fabricating a package includes several processes. FIG. 10 illustrates an exemplary flow diagram of a method 1000 for providing or fabricating a package. In some implementations, the method 1000 of FIG. 10 may be used to provide or fabricate the package 500 described in the disclosure. However, the method 1000 may be used to provide or fabricate any of the packages (e.g., 100) described in the disclosure.

It should be noted that the method 1000 of FIG. 10 may combine one or more processes in order to simplify and/or clarify the method for providing or fabricating a package. In some implementations, the order of the processes may be changed or modified.

The method provides (at 1005) a substrate. Stage 1 of FIG. 9A, illustrates and describes an example of a state after a substrate 102 is provided. The substrate 102 may be a first substrate. The substrate 102 includes at least one dielectric layer 120 and a plurality of interconnects 122. The substrate 102 may include a first surface (e.g., top surface) and a second surface (e.g., bottom surface). The substrate 102 may include solder resist layers. The substrate 102 may be fabricated using the method as described in FIGS. 11A-11B.

The method couples (at 1010) integrated devices to the substrate. Stage 2 of FIG. 9A, illustrates and describes an example of a state after an integrated device 103 and an integrated device 503 are coupled to the first surface (e.g., top surface) of the substrate 102. The integrated device 103 may be coupled to the substrate 102 through the plurality of pillar interconnects 130 and the plurality of solder interconnects 132. In some implementations, the integrated device 103 may be coupled to the substrate 102 through the plurality of solder interconnects 132. The integrated device 503 may be coupled to the substrate 102 through the plurality of pillar interconnects 530 and the plurality of solder interconnects 532. In some implementations, the integrated device 503 may be coupled to the substrate 102 through the plurality of solder interconnects 532. A solder reflow process may be used to couple the integrated device 103 and/or the integrated device 503 to the substrate 102.

The method provide and/or forms (at 1015) an underfill. Stage 3 of FIG. 9A, illustrates and describes an example of a state after an underfill 104 is formed, dispensed and/or provided. The underfill 104 may be located between the integrated device 103 and the substrate 102. The underfill 104 may be located between the integrated device 503 and the substrate 102. The underfill 104 may be located between the integrated device 103 and the integrated device 503. A flow process may be used to provide the underfill 104.

The method provides and/or forms (at 1020) a back side dielectric layer. Stage 4 of FIG. 9B, illustrates and describes an example of a state after a back side dielectric layer 106 is formed and provided. The back side dielectric layer 106 may be provided over a surface of the substrate 102, a surface of the underfill 104, at least one surface of the integrated device 103 and at least one surface of the integrated device 503. A vapor deposition process (e.g., micro vapor deposition process) may be used to form the back side dielectric layer 106. The back side dielectric layer 106 may include silicon oxide (e.g., silicon dioxide). The back side dielectric layer 106 may be optional.

The method forms (at 1025) openings in the back side dielectric layer. Stage 5 of FIG. 9B, illustrates and describes an example of a state after a plurality of openings 906 are formed in the back side dielectric layer 106. A laser process or an etching process with a mask may be used to form the plurality of openings 906 in the back side dielectric layer 106.

The method forms (at 1030) a plurality of back side interconnects. Stage 6 of FIG. 9C, illustrates and describes an example of a state after a plurality of back side interconnects 507 are formed. The plurality of back side interconnects 507 may be coupled to the plurality of interconnects 122 of the substrate 102. The plurality of back side interconnects 507 may be formed over and coupled to the back side dielectric layer 106. The plurality of back side interconnects 507 may be located over the underfill 104 and the integrated device 103 and/or the integrated device 503. When the back side dielectric layer 106 is optional, the plurality of back side interconnects 507 may be coupled to and touching a surface of the underfill 104, at least one surface of the integrated device 103 and at least one surface of the integrated device 503. An inkjet printing process may be used to form the plurality of back side interconnects 507. In some implementations, a plating process may be used to form the plurality of back side interconnects 507. The plurality of back side interconnects 507 may include silver (Ag) or copper (Cu).

The method couples (at 1035) a plurality of solder interconnects to the substrate. Stage 7 of FIG. 9C, illustrates and describes an example of a state after a plurality of solder interconnects 114 are coupled to the second surface of the substrate 102. A solder reflow process may be used to couple the plurality of solder interconnects 114 to the substrate 102. Stage 8 may illustrate the package 500.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Substrate

In some implementations, fabricating a substrate includes several processes. FIGS. 11A-11B illustrate an exemplary sequence for providing or fabricating a substrate. In some implementations, the sequence of FIGS. 11A-11B may be used to provide or fabricate the substrate 102. However, the process of FIGS. 11A-11B may be used to fabricate any of the substrates described in the disclosure.

It should be noted that the sequence of FIGS. 11A-11B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 11A, illustrates a state after a carrier 1100 is provided. A seed layer 1101 may be located over the carrier 1100.

Stage 2 illustrates a state after a plurality of interconnects 1112 are formed. The interconnects 1112 may be located over the seed layer 1101. A lithography process, a plating process, a strip process and/or an etching process may be used to form the plurality of interconnects 1112. The interconnects 1112 may represent at least some of the interconnects from the plurality of interconnects 122.

Stage 3 illustrates a state after a dielectric layer 1110 is formed over the carrier 1100, the seed layer 1101 and the plurality of interconnects 1112. A deposition and/or lamination process may be used to form the dielectric layer 1110. The dielectric layer 1110 may include prepreg and/or polyimide. The dielectric layer 1110 may include a photo-imageable dielectric. However, different implementations may use different materials for the dielectric layer.

Stage 4 illustrates a state after a plurality of cavities 1113 is formed in the dielectric layer 1110. The plurality of cavities 1113 may be formed using an etching process (e.g., photo etching process), a laser process, an exposure process and/or a development process.

Stage 5 illustrates a state after interconnects 1122 are formed in and over the dielectric layer 1110, including in and over the plurality of cavities 1113. For example, a via, pad and/or traces may be formed. A lithography process, a plating process, a strip process and/or an etching process may be used to form the interconnects.

Stage 6, as shown in FIG. 11B, illustrates a state after a dielectric layer 1120 is formed over the dielectric layer 1110 and the plurality of interconnects 1122. A deposition and/or lamination process may be used to form the dielectric layer 1120. The dielectric layer 1120 may include prepreg and/or polyimide. The dielectric layer 1120 may include a photo-imageable dielectric. However, different implementations may use different materials for the dielectric layer.

Stage 7, illustrates a state after a plurality of cavities 1123 is formed in the dielectric layer 120. The dielectric layer 120 may represent the dielectric layer 1110 and/or the dielectric layer 1120. The plurality of cavities 1123 may be formed using an etching process (e.g., photo etching process), a laser process, an exposure process and/or a development process.

Stage 8 illustrates a state after interconnects 1132 are formed in and over the dielectric layer 140, including in and over the plurality of cavities 1123. For example, a via, pad and/or traces may be formed. A lithography process, a plating process, a strip process and/or an etching process may be used to form the interconnects.

Stage 9 illustrates a state after the carrier 1100 is decoupled (e.g., detached, removed, grinded out) from at least one dielectric layer 120 and the seed layer 1101, portions of the seed layer 1101 are removed (e.g., etched out), leaving the substrate 102 that includes at least one dielectric layer 120 and the plurality of interconnects 122. The plurality of interconnects 122 may represent the plurality of interconnects 1112, the plurality of interconnects 1122 and/or the plurality of interconnects 1132.

Stage 10 illustrates a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. The solder resist layer 124 and/or the solder resist layer 126 may include openings. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

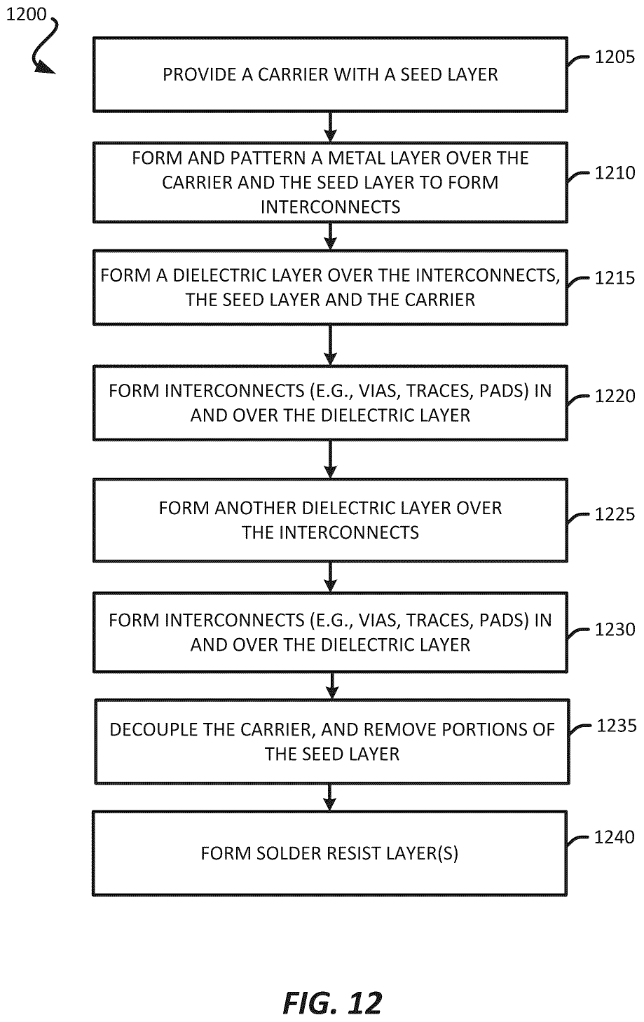

In some implementations, fabricating a substrate includes several processes. FIG. 12 illustrates an exemplary flow diagram of a method 1200 for providing or fabricating a substrate. In some implementations, the method 1200 of FIG. 12 may be used to provide or fabricate the substrate(s) of the disclosure. For example, the method 1200 of FIG. 12 may be used to fabricate the substrate 102.

It should be noted that the method 1200 of FIG. 12 may combine one or more processes in order to simplify and/or clarify the method for providing or fabricating a substrate. In some implementations, the order of the processes may be changed or modified.

The method provides (at 1205) a carrier with a seed layer. Stage 1 of FIG. 11A, illustrates and describes an example of a state after a carrier 1100 is provided. A seed layer 1101 may be located over the carrier 1100.

The method forms and patterns (at 1210) a plurality of interconnects. Stage 2 of FIG. 11A, illustrates and describes an example of a state after a plurality of interconnects 1112 are formed. The interconnects 1112 may be located over the seed layer 1101. A lithography process, a plating process, a strip process and/or an etching process may be used to form the plurality of interconnects 1112. The interconnects 1112 may represent at least some of the interconnects from the plurality of interconnects 122.

The method forms (at 1215) a dielectric layer. Stage 3 of FIG. 11A, illustrates and describes an example of a state after a dielectric layer 1110 is formed over the carrier 1100, the seed layer 1101 and the plurality of interconnects 1112. A deposition and/or lamination process may be used to form the dielectric layer 1110. The dielectric layer 1110 may include prepreg and/or polyimide. The dielectric layer 1110 may include a photo-imageable dielectric. However, different implementations may use different materials for the dielectric layer.

The method forms (at 1220) a plurality of interconnects. Forming a plurality of interconnects may including forming a plurality of cavities in a dielectric layer and a performing a plating process. Stage 4 of FIG. 11A, illustrates and describes an example of a state after a plurality of cavities 1113 is formed in the dielectric layer 1110. The plurality of cavities 1113 may be formed using an etching process (e.g., photo etching process), a laser process, an exposure process and/or a development process.

Stage 5 of FIG. 11A, illustrates and describes an example of a state after interconnects 1122 are formed in and over the dielectric layer 1110, including in and over the plurality of cavities 1113. For example, a via, pad and/or traces may be formed. A lithography process, a plating process, a strip process and/or an etching process may be used to form the interconnects.

The method forms (at 1225) another dielectric layer. Stage 6 of FIG. 11B, illustrates and describes an example of a state after a dielectric layer 1120 is formed over the dielectric layer 1110 and the plurality of interconnects 1122. A deposition and/or lamination process may be used to form the dielectric layer 1120. The dielectric layer 1120 may include prepreg and/or polyimide. The dielectric layer 1120 may include a photo-imageable dielectric. However, different implementations may use different materials for the dielectric layer.

The method forms (at 1230) a plurality of interconnects. Forming a plurality of interconnects may including forming a plurality of cavities in a dielectric layer and a performing a plating process. Stage 7 of FIG. 11B, illustrates and describes an example of a state after a plurality of cavities 1123 is formed in the dielectric layer 140. The dielectric layer 140 may represent the dielectric layer 1110 and/or the dielectric layer 1120. The plurality of cavities 1123 may be formed using an etching process (e.g., photo etching process), a laser process, an exposure process and/or a development process.

Stage 8 of FIG. 11B, illustrates and describes an example of a state after interconnects 1132 are formed in and over the dielectric layer 120, including in and over the plurality of cavities 1123. For example, a via, pad and/or traces may be formed. A lithography process, a plating process, a strip process and/or an etching process may be used to form the interconnects.

The method decouples (at 1235) a carrier. Stage 9 of FIG. 11B, illustrates and describes an example of a state after the carrier 1100 is decoupled (e.g., detached, removed, grinded out) from at least one dielectric layer 140 and the seed layer 1101, portions of the seed layer 1101 are removed (e.g., etched out), leaving the substrate 102 that includes at least one dielectric layer 120 and the plurality of interconnects 122. The plurality of interconnects 122 may represent the plurality of interconnects 1112, the plurality of interconnects 1122 and/or the plurality of interconnects 1132.

The method forms (at 1240) solder resist layers. Stage 10 of FIG. 11B, illustrates and describes an example of a state after the solder resist layer 124 is formed over the first surface of the substrate 102, and after the solder resist layer 126 is formed over the second surface of the substrate 102. A deposition process and/or lamination process may be used to form the solder resist layer 124 and/or the solder resist layer 126. An etching process, an exposure process and/or a development process may be used to form the openings in the solder resist layer 124 and/or the openings in the solder resist layer 126.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Electronic Devices

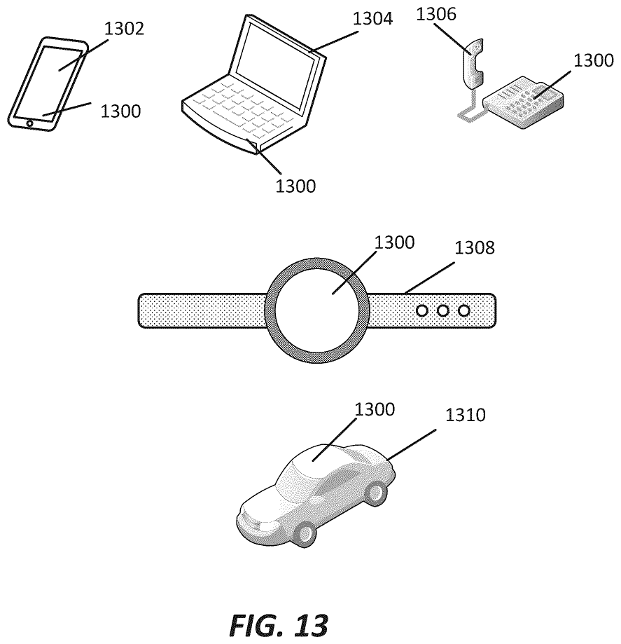

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-8, 9A-9C, 10, 11A-11B, and 12-13 may be rearranged and/or combined into a single component, process, feature or function or embodied in several components, processes, or functions. Additional elements, components, processes, and/or functions may also be added without departing from the disclosure. It should also be noted FIGS. 1-8, 9A-9C, 10, 11A-11B, and 12-13 and its corresponding description in the present disclosure is not limited to dies and/or ICs. In some implementations, FIGS. 1-8, 9A-9C, 10, 11A-11B, and 12-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a substrate; a first integrated device coupled to the substrate through at least a first plurality of solder interconnects; an underfill located between the first integrated device and the substrate; and a back side interconnect located over the underfill and a back side of the first integrated device.

Aspect 2: The package of aspect 1, wherein the back side interconnect is coupled to and touching a surface of the underfill and a surface of the first integrated device.

Aspect 3: The package of aspect 1, further comprising a back side dielectric layer coupled to the underfill and the first integrated device.

Aspect 4: The package of aspect 3, wherein the back side interconnect is coupled to the back side dielectric layer.

Aspect 5: The package of aspect 4, wherein a part of the back side dielectric layer is located between the back side interconnect and the underfill.

Aspect 6: The package of aspect 4, wherein a part of the back side dielectric layer is located between the back side interconnect and the first integrated device.

Aspect 7: The package of aspects 1 through 6, wherein the substrate comprises at least one dielectric layer; and a plurality of interconnects, wherein the back side interconnect is coupled to a first interconnect and a second interconnect from the plurality of interconnects of the substrate.

Aspect 8: The package of aspects 1 through 7, further comprising a second integrated device coupled to the substrate through at least a second plurality of solder interconnects, wherein the underfill is located between the second integrated device and the substrate.

Aspect 9: The package of aspect 8, wherein the back side interconnect is further located over a back side of the second integrated device.

Aspect 10: The package of aspect 9, wherein the underfill is further located between the first integrated device and the second integrated device.

Aspect 11: The package of aspect 10, wherein the back side interconnect extends between a back side of the first integrated device and a back side of the second integrated device.

Aspect 12: The package of aspect 10, further comprising a back side dielectric layer coupled to the underfill, a back side of the first integrated device and a back side of the second integrated device.

Aspect 13: The package of aspect 12, wherein a first part of the back side dielectric layer is located between a first part of the back side interconnect and a back side of the first integrated device, and wherein a second part of the back side dielectric layer is located between a second part of the back side interconnect and a back side of the second integrated device.

Aspect 14: The package of aspect 13, wherein a third part of the back side dielectric layer is located between a third part of the back side interconnect and a surface of the underfill.

Aspect 15: The package of aspects 12 through 14, wherein the back side dielectric layer is coupled to the substrate.

Aspect 16: The package of aspects 12 through 15, wherein the back side dielectric layer includes silicon oxide.

Aspect 17: The package of aspect 8, wherein the first integrated device is coupled to the substrate through a first plurality of pillar interconnects and the first plurality of solder interconnects, and wherein the second integrated device is coupled to the substrate through a second plurality of pillar interconnects and the second plurality of solder interconnects.

Aspect 18: The package of aspects 1 through 17, wherein the back side interconnect includes copper (Cu) or silver (Ag).

Aspect 19: The package of aspects 1 through 17, wherein the back side interconnect includes an inkjet printed interconnect.

Aspect 20: The package of aspects 1 through 17, wherein the back side interconnect includes plated interconnects.

Aspect 21: A device comprising the package of aspects 1 through 20, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: A method for fabricating a package. The method provides a substrate. The method couples a first integrated device to the substrate through at least a first plurality of solder interconnects. The method forms an underfill between the first integrated device and the substrate. The method forms a back side interconnect located over the underfill and a back side of the first integrated device.

Aspect 23: The method of aspect 22, wherein the back side interconnect is coupled to and touching a surface of the underfill and a surface of the first integrated device.

Aspect 24: The method of aspect 22, further providing a back side dielectric layer coupled to the underfill and the first integrated device.

Aspect 25: The method of aspect 24, wherein the back side interconnect is coupled to the back side dielectric layer.

Aspect 26: The method of aspect 25, wherein a part of the back side dielectric layer is located between the back side interconnect and the underfill.

Aspect 27: The method of aspect 25, wherein a part of the back side dielectric layer is located between the back side interconnect and the first integrated device.

Aspect 28: The method of aspects 22 through 27, wherein the back side interconnect includes copper (Cu) or silver (Ag).

Aspect 29: The method of aspects 22 through 27, wherein the back side interconnect includes an inkjet printed interconnect.

Aspect 30: The method of aspects 22 through 27, wherein the back side interconnect includes plated interconnects.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
a first integrated device coupled to the substrate through at least a first plurality of solder interconnects;
an underfill located between the first integrated device and the substrate; and
a back side interconnect located over the underfill and a back side of the first integrated device.

2. The package of claim 1, wherein the back side interconnect is coupled to and touching a surface of the underfill and a surface of the first integrated device.

3. The package of claim 1, further comprising a back side dielectric layer coupled to the underfill and the first integrated device.

4. The package of claim 3, wherein the back side interconnect is coupled to the back side dielectric layer.

5. The package of claim 4, wherein a part of the back side dielectric layer is located between the back side interconnect and the underfill.

6. The package of claim 4, wherein a part of the back side dielectric layer is located between the back side interconnect and the first integrated device.

7. The package of claim 1,
wherein the substrate comprises:
at least one dielectric layer; and
a plurality of interconnects, and
wherein the back side interconnect is coupled to a first interconnect and a second interconnect from the plurality of interconnects of the substrate.

8. The package of claim 1, further comprising a second integrated device coupled to the substrate through at least a second plurality of solder interconnects, wherein the underfill is located between the second integrated device and the substrate.

9. The package of claim 8, wherein the back side interconnect is further located over a back side of the second integrated device.

10. The package of claim 9, wherein the underfill is further located between the first integrated device and the second integrated device.

11. The package of claim 10, wherein the back side interconnect extends between a back side of the first integrated device and a back side of the second integrated device.

12. The package of claim 10, further comprising a back side dielectric layer coupled to the underfill, a back side of the first integrated device and a back side of the second integrated device.

13. The package of claim 12,
wherein a first part of the back side dielectric layer is located between a first part of the back side interconnect and a back side of the first integrated device, and
wherein a second part of the back side dielectric layer is located between a second part of the back side interconnect and a back side of the second integrated device.

14. The package of claim 13, wherein a third part of the back side dielectric layer is located between a third part of the back side interconnect and a surface of the underfill.

15. The package of claim 12, wherein the back side dielectric layer is coupled to the substrate.

16. The package of claim 12, wherein the back side dielectric layer includes silicon oxide.

17. The package of claim 8,
wherein the first integrated device is coupled to the substrate through a first plurality of pillar interconnects and the first plurality of solder interconnects, and
wherein the second integrated device is coupled to the substrate through a second plurality of pillar interconnects and the second plurality of solder interconnects.

18. The package of claim 1, wherein the back side interconnect includes copper (Cu) or silver (Ag).

19. The package of claim 1, wherein the back side interconnect includes an inkjet printed interconnect.

20. The package of claim 1, wherein the back side interconnect includes plated interconnects.
